(19) United States
(12) Patent Application Publication
(10) Pub. No.: US 2012/0069516 A1
(43) Pub. Date: Mar. 22, 2012

(54) ELECTRONIC APPARATUS

(75) Inventor: Yoshiaki NAGAMURA, Osaka (JP)

(73) Assignee: PANASONIC CORPORATION, Osaka (JP)

(21) Appl. No.: 13/237,494

(22) Filed: Sep. 20, 2011

(30) Foreign Application Priority Data
Sep. 22, 2010 (JP) 2010-212513

(51) Int. Cl. H05K 5/02

(52) U.S. Cl. 361/679.55

(57) ABSTRACT

By forming a back wall in a holding member capable of holding a cable connector, an opening portion can be closed by the back wall in the case of producing a notebook computer not having a modular port. Therefore, one holding member can realize a notebook computer having a modular port and a notebook computer not having a modular port. This configuration makes it possible to eliminate the necessity to prepare a lid separately when the notebook computer does not have the modular port and to correspond to a plurality of specifications of communication interfaces with a reduced number of components. The reduction in the number of components reduces the cost of the notebook computer and the number of steps in assembling the notebook computer.

### BACKGROUND OF THE INVENTION

1. Field of the Invention

The present application relates to an electronic apparatus having a communication interface.

2. Description of Related Art

In many cases, recent notebook computers have a LAN (Local Area Network) port to/from which a LAN cable is attachable/detachable, a modular port to/from which a modular cable is attachable/detachable, or both of these ports.

Patent Document 1 (JP 2003-092170 A) relates to an electronic apparatus having openings in a face of a housing for attaching/detaching plural kinds of cable connectors, and discloses a configuration that allows only one type of connecters, which are disposed adjacent to each other and have different standards, to be used.

However, in the configuration disclosed by Patent Document 1, in order to prevent the cable connector from being inserted mistakenly into the connector not to be used, a lid should be prepared separately for closing the opening portion, which increases the number of components.

### SUMMARY OF THE INVENTION

Therefore, an electronic apparatus disclosed in the present application is an electronic apparatus that can have a connector to which a communication cable is connectable, including: a housing having an opening portion to which the communication cable is insertable; and a holding member contained in the housing and capable of holding the connector. The holding member includes a notch portion for exposing a communication cable connection portion in the connector to the outside, and a wall portion having a size sufficient to close the opening portion. The holding member can be placed in the housing in a first posture in which the notch portion faces the opening portion or in a second posture in which the wall portion closes the opening portion.

According to the present application, it is possible to correspond to various interface specifications with a reduced number of components.

### BRIEF DESCRIPTION OF THE DRAWINGS

FIG. 1 is a perspective view of a notebook computer according to the present embodiment.

FIG. 2 is a perspective view of the vicinity of an opening portion in a first housing.

FIG. 3 is a perspective view of the vicinity of the opening portion in the first housing.

FIG. 4A is a perspective view of a holding member.

FIG. 4B is a perspective view of the holding member.

FIG. 5 is a perspective view of the vicinity of an opening portion of a bottom case.

FIG. 6 is a cross-sectional view taken along a line W-W in FIG. 2.

FIG. 7 is a cross-sectional view taken along a line W′-W′ in FIG. 3.

FIG. 8A is a perspective view of a holding member.

FIG. 8B is a perspective view of the holding member.

FIG. 8C is a perspective view of the holding member.

FIG. 9 is a perspective view of the vicinity of an opening portion of a bottom case.

FIG. 10 is a cross-sectional view taken along the line W-W in FIG. 2.

FIG. 11 is a cross-sectional view taken along a line V-V in FIG. 2.

FIG. 12 is a cross-sectional view taken along the line W′-W′ in FIG. 3.

FIG. 13 is a cross-sectional view taken along a line V′-V′ in FIG. 3.

### DETAILED DESCRIPTION OF THE INVENTION

### Embodiment

[1. Configuration of Electronic Apparatus]

Recently, specifications of communication interfaces of notebook computers may vary depending on the product grade and the product destination. For example, a model having a LAN port only, a model having a modular port only, and a model having both of the LAN port and the modular port are produced selectively.

The LAN port and the modular port include a cable connector. The cable connecter is arranged so as to be visible from outside via an opening portion formed in a housing. Therefore, conventionally, in a case of producing the model having a LAN port only, a housing having an opening portion corresponding to the LAN port is produced; whereas, in a case of producing the model having a modular port only, a housing having an opening portion corresponding to the modular port is produced. In other words, housings need be produced in accordance with the specification of the communication interface of the notebook computer, which increases the production cost.

Further, there is a configuration in which an opening portion corresponding to a LAN port and an opening portion corresponding to a modular port are formed in a housing, and an unnecessary opening portion is closed using a lid in accordance with the specification of the communication interface. For example, in a case of producing the model having a LAN port only, the opening portion corresponding to the modular port is closed by a lid. However, in such a configuration, since the lid needs to be produced separately, the production cost is increased. Further, since a structure of holding the cable connector of each port as well as a structure of holding the lid need to be provided, an internal structure of the housing becomes complicated.

An electronic apparatus according to the present invention can be realized as a notebook computer that corresponds to various types of communication interfaces with a simple configuration.

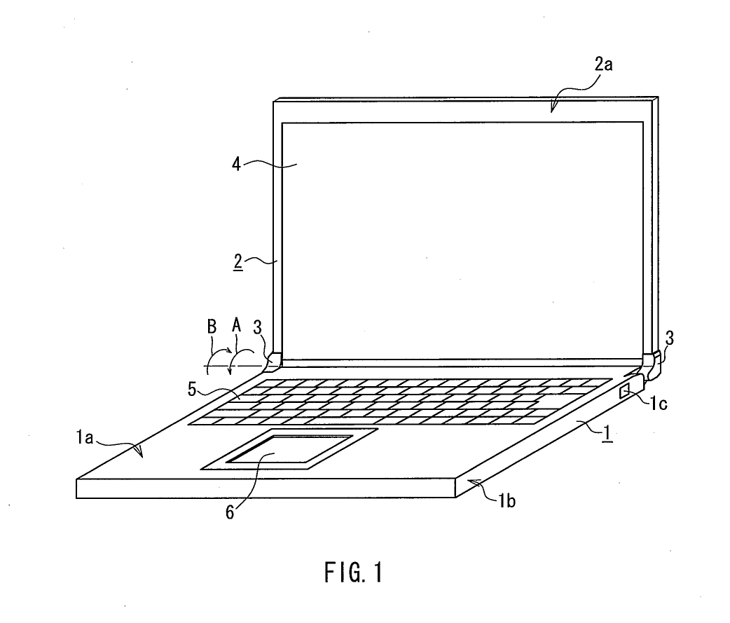

FIG. 1 is a perspective view showing an appearance of a notebook computer according to the present embodiment.

As shown in FIG. 1, the notebook computer has a first housing 1 and a second housing 2. The first housing 1 contains a circuit board on which various electric elements are mounted, a hard disk drive, and the like. The second housing 2 has a liquid crystal display 4. The first housing 1 and the second housing 2 are supported rotatably by hinges 3. The hinges 3 have a rotation shaft supporting the first housing 1 and the second housing 2 rotatably in a direction indicated by an arrow A or B. A keyboard 5 and a pointing device 6 are provided on an upper face 1a of the first housing 1.

An opening portion 1c is formed in a first side face 1b of the first housing 1. The opening portion 1c has a modular port selectively. Although in the present embodiment only one opening portion 1c is formed in the first side face 1b of the first housing 1, other opening portions, e.g., an opening portion for selectively having a LAN port, may be formed further. Here, “selectively having” indicates that the opening portion 1c may have a form having a modular port or a form not having a modular port selectively.

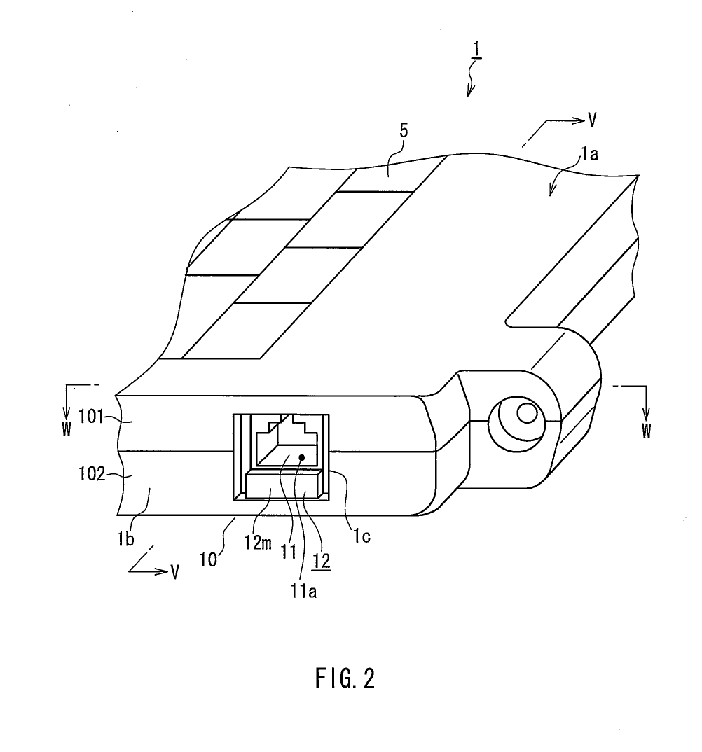

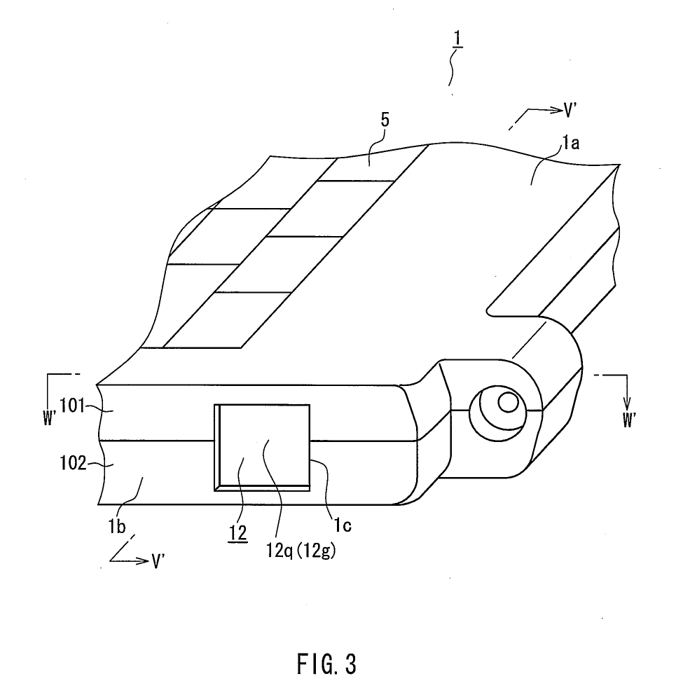

FIGS. 2 and 3 are partial perspective views of the vicinity of the opening portion 1c in the first housing 1. FIG. 2 shows a form in which the first housing 1 has a modular port 10, and a cable connector 11 and the like are exposed via the opening portion 1c. FIG. 3 shows a form in which the first housing 1 does not have the modular port 10, and the opening portion 1c is closed. In other words, in accordance with the specification of the communication interface, the notebook computer of the present embodiment may have the form shown in FIG. 2 or the form shown in FIG. 3 selectively.

As shown in FIGS. 2 and 3, a top case 101 and a bottom case 102 are joined to each other so as to form the first housing 1 of the present embodiment.

As shown in FIG. 2, when the first housing 1 has the modular port 10, the cable connector 11 and a holding member 12 are arranged in the vicinity of the opening portion 1c in the first housing 1. Further, as shown in FIG. 3, when the first housing 1 does not have the modular port 10, only the holding member 12 is arranged in the vicinity of the opening portion 1c in the first housing 1. The opening portion 1c shown in FIG. 3 is closed by a wall face 12q (12g) of the holding member 12. In other words, the holding member 12 has a structure of holding the cable connector 11 and a structure of closing the opening portion 1c. Hereinafter, the configuration of the holding member 12 will be described.

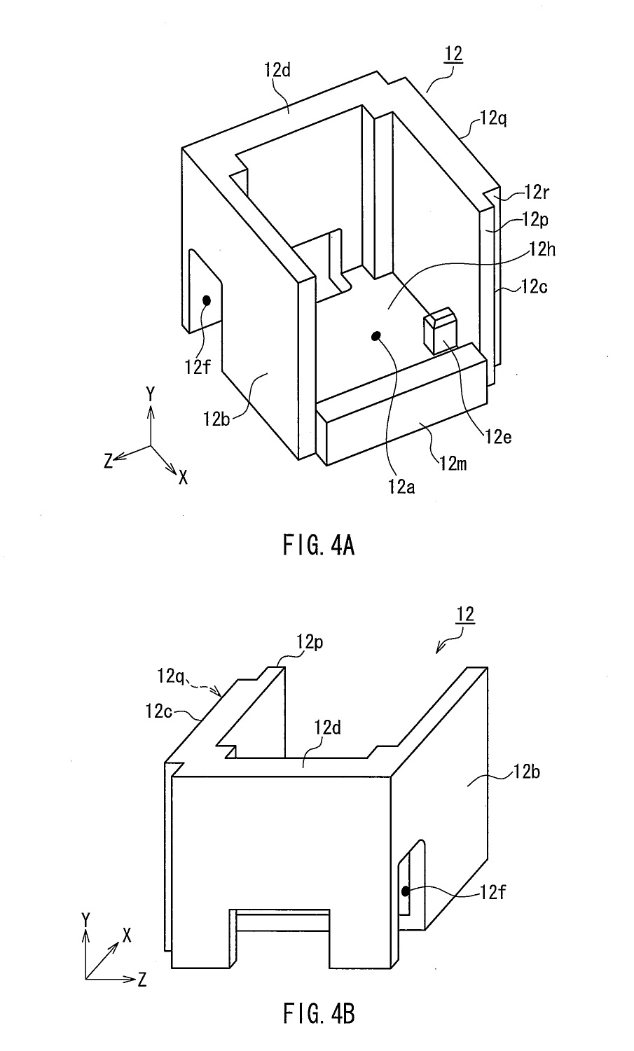

FIG. 4A is a perspective view mainly showing a front side of the holding member 12. FIG. 4B is a perspective view mainly showing a back side of the holding member 12. The holding member 12 includes a connector placement portion 12a, a first side wall 12b, a second side wall 12c, a back wall 12d, a protrusion 12e, a hole 12f, a bottom portion 12h, a front wall 12m and the wall face 12q. In the present invention, in the holding member 12, a side where the front wall 12m is formed with respect to the connector placement portion 12a is defined as “front”, a side where the back wall 12d is formed with respect to the connector placement portion 12a is defined as “back”, a first side wall side positioned on the left side when the back wall 12d is viewed from the front wall 12m is defined as “left”, and a second side wall side positioned on the right side when viewed from the front is defined as “right”.

The connector placement portion 12a is a space where the cable connector 11 can be placed. The first side wall 12b and the second side wall 12c are opposed to each other with the connector placement portion 12a interposed therebetween. The first side wall 12b and the second side wall 12c can regulate the position of the cable connector 11 placed in the connector placement portion 12a, in a Z-axis direction shown in the drawings, i.e., in left and right directions. The second side wall 12c is placed in the right direction of the connector placement portion 12a, and includes the wall face 12q that is adjacent to the back wall 12d and an opening face 12p forming the opening portion 1c via a notch 12r formed as a step. The back wall 12d and the front wall 12m can regulate the position of the cable connector 11 placed in the connector placement portion 12a in a X-axis direction.

The protrusion 12e is a member for regulating the position of the cable connector 11 placed in the connector placement portion 12a, in the X-axis direction shown in the drawings, i.e., in front and back directions. The protrusion 12e is formed in such a manner as to contact the second side wall 12c and the bottom portion 12h. Although the illustration is omitted, a protrusion similar to the protrusion 12e also is formed in such a manner as to contact the first side wall 12b and the bottom portion 12h. Further, although the illustration of the specific configuration is omitted, the cable connector 11 has a concave portion where the protrusion 12e can be fitted.

The hole 12f is formed for insertion of a conductive wire material (not illustrated) that is connected electrically to the cable connector 11.

The wall face 12q is a face on a right side of the second side wall 12c. The wall face 12q is a face in the second side wall 12c on a side opposite to the connector placement portion 12a. The wall face 12q has a shape and an area sufficient to close at least the opening portion 1c. In the present embodiment, the wall face 12q has an area slightly smaller than an opening area of the opening portion 1c. Note here that “a shape and an area sufficient to close the opening portion 1c” includes a shape and an area that create a slight gap between the wall face 12q and the opening portion 1c when the opening portion 1c is closed by the second side wall 12c, and a shape that does not create any gap between the second side wall 12c and the opening portion 1c, i.e., a shape and an area that cause the wall face 12q to be press-fitted in the opening portion 1c. The second side wall 12c need not have a shape and an area sufficient to close the opening portion 1c as exemplified in the present embodiment, as long as at least the shape and the area close the opening portion 1c to the extent that a communication cable can be prevented from being attached to the cable connector 11.

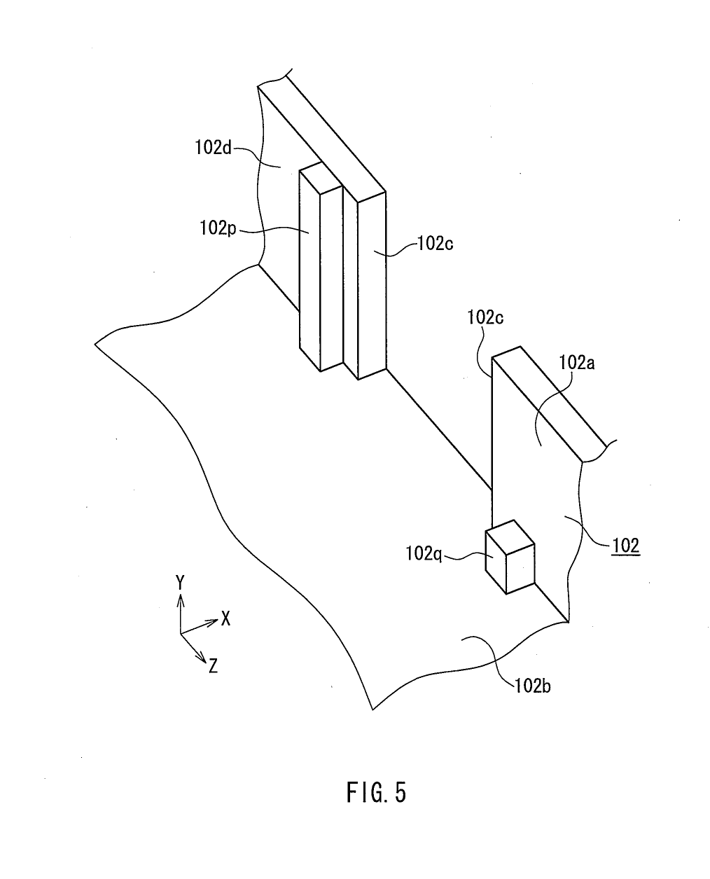

FIG. 5 is a partial perspective view of the bottom case 102 in the vicinity of the opening portion 1c of the first housing 1. As shown in FIG. 5, the bottom case 102 includes a bottom portion 102b, and side walls 102a and 102d arranged vertically on the periphery of the bottom portion 102b. A notch 102c forming the opening portion 1c is formed between the side walls 102a and 102d. Positioning ribs 102p and 102q respectively are arranged vertically along the side walls 102d and 102a from the bottom portion 102b. Although in the present embodiment a length in the positioning rib 102p in a direction along the side wall 102d is longer than a length in the positioning rib 102q in a direction along the side wall 102a, these ribs may have the same length.

Hereinafter, specific configurations of the notebook computer in the case of having the modular port 10 and in the case of not having the modular port 10 will be described.

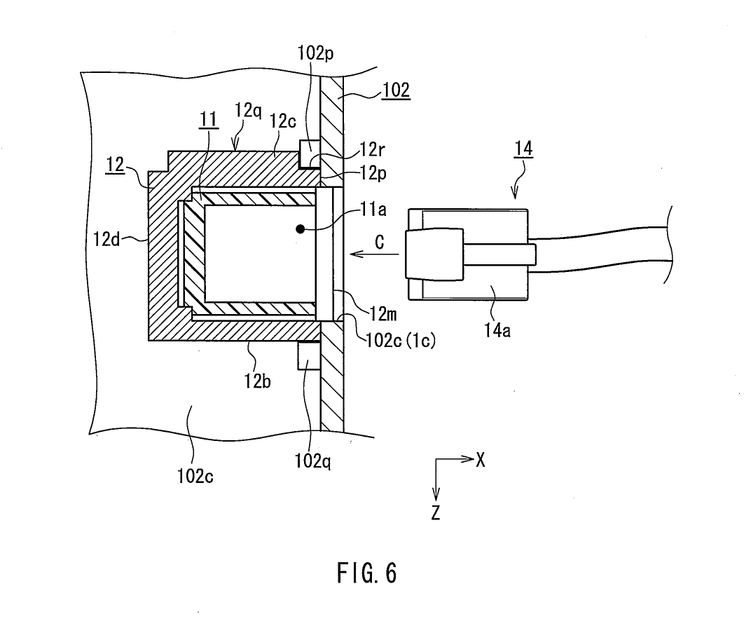

FIG. 6 is a main portion cross-sectional view of the notebook computer having the modular port 10. FIG. 6 is a cross-sectional view taken along a line W-W in FIG. 2.

In the case where the notebook computer has the modular port 10 (see FIG. 2), firstly, as shown in FIG. 6, the cable connector 11 is placed in the connector placement portion 12a of the holding member 12. At this time, the position of the cable connector 11 is regulated by the protrusion 12e (see FIG. 4A, etc.) formed in the holding member 12. Further, a conductive wire material (not illustrated) provided in the cable connector 11 is inserted in the hole 12f (see FIG. 4A, etc.) so as to be connected electrically to an electric circuit board (not illustrated) arranged in the first housing 1.

Next, the holding member 12 holding the cable connector 11 is arranged in a predetermined position of the bottom case 102, i.e., in the vicinity of the notch 102c. At this time, the holding member 12 is arranged in the predetermined position of the bottom case 102 with the front wall 12m side facing the notch 102c side. When the notch 12r in the opening face 12p, which corresponds to a protrusion height of the wall face 12q in the second side wall 12c, engages with the positioning rib 102p and the first side wall 12b comes into contact with the positioning rib 102q, the position of the holding member 12 in the Z-axis direction is regulated.

Next, the top case 101 is joined to the bottom case 102. By joining the top case 101 to the bottom case 102, the cable connector 11 and the holding member 12 are sandwiched by the top case 101 and the bottom case 102, whereby the position in upper and lower directions (thickness direction of the first housing 1), i.e., the position in a Y-axis direction (upper and lower directions) in FIGS. 4A and 4B is regulated.

In this manner, the modular port 10 can be provided in the notebook computer. By this, as shown in FIG. 2, an opening portion 11a of the cable connector 11 is exposed from the first housing 1, which allows a connector 14a of a modular cable 14 to be connected to the cable connector 11 when displaced in a direction indicated by an arrow C as shown in FIG. 6.

Note here that, by putting a mark or a character expressing a modular port on the front wall 12m, it is possible to notify a user that the port exposed from the opening portion 1c is a modular port.

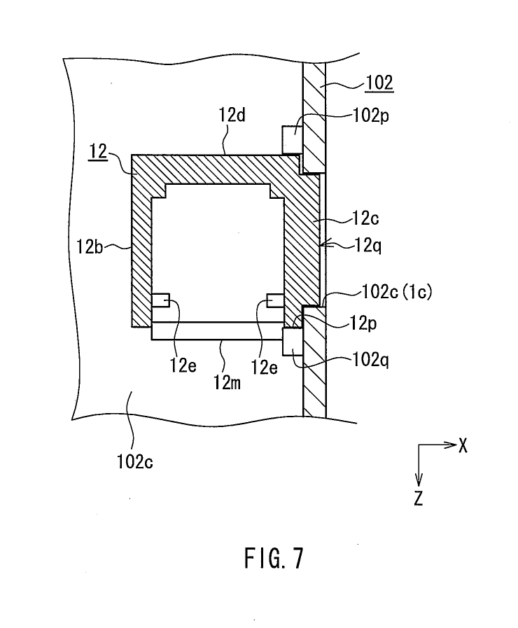

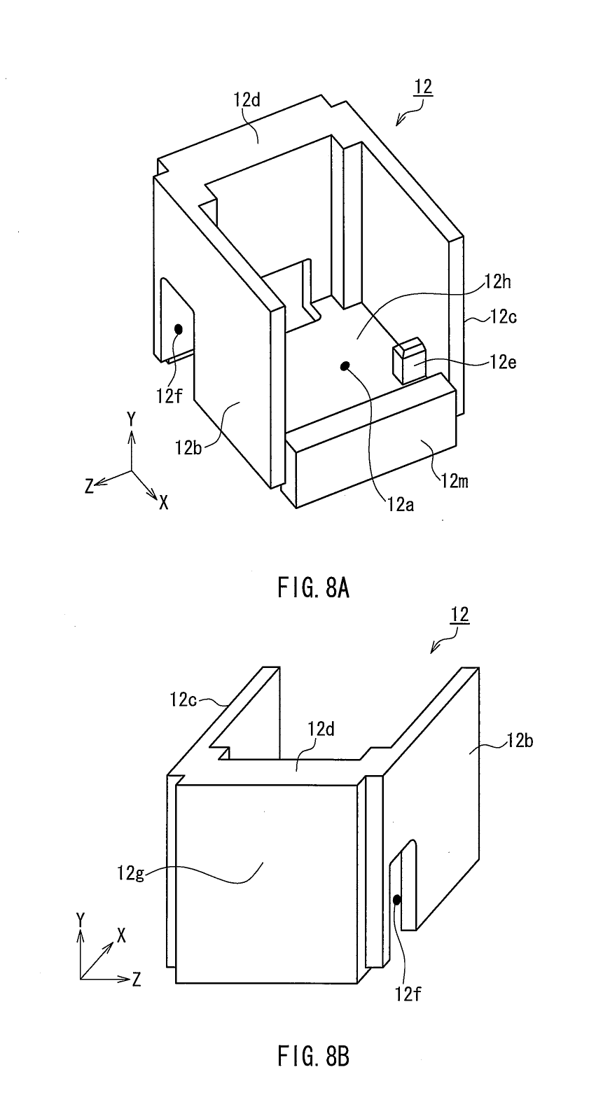

FIG. 7 is a main portion cross-sectional view of the notebook computer not having the modular port 10. FIG. 8 is a cross-sectional view taken along a line W′-W′ in FIG. 3.

As shown in FIG. 7, also in the case where the notebook computer does not have the modular port 10, the holding member 12 is arranged in the predetermined position of the bottom case 102, i.e., in the vicinity of the notch 102c. However, in this case, the holding member 12 is arranged in the predetermined position of the bottom case 102 with the second side wall 12c and the wall face 12q side facing the notch 102c side. When the second side wall 12c of the holding member 12 is fitted to the notch 102c, and the back wall 12d and the opening face 12p come into contact with the positioning ribs 102p and 102q, respectively, the position in the Z-axis direction of the bottom case 102 is regulated.

Next, the top case 101 is joined to the bottom case 102. By joining the top case 101 to the bottom case 102, the holding member 12 is sandwiched by the top case 101 and the bottom case 102, whereby the position in the thickness direction of the first housing 1, i.e., the position in the Y-axis direction (upper and lower directions) is regulated.

In this manner, as shown in FIG. 3, the wall face 12q of the second side wall 12c of the holding member 12 is exposed via the opening portion 1c. Further, since the wall face 12q at least has an area slightly smaller than the opening area of the opening portion 1c, a part of the second side wall 12c is positioned in the opening portion 1c by placing the holding member 12 in the first housing 1 in a posture shown in FIG. 7. Thus, the opening portion 1c can be closed by the wall face 12q.

Note here that the positioning ribs 102p and 102q that are formed in the bottom case 102 and explained using FIG. 5 can be formed so as to extend to the top case 101, which is joined to the bottom case 102. In other words, in order to regulate the position on the extension of the positioning ribs 102p and 102q, ribs can be formed on a side wall of the top case 101 in such a manner as to be parallel to the opening portion 102c in the side walls 102a and 102d of the bottom case 102. Further, it is possible to form the rib for regulating the Z-axis direction of the holding member 12 only in the top case 101 without forming the rib in the bottom case 102. Further, as explained using FIG. 7, since the wall face 12q engages with the notch 102c and the holding member 12 is fixed by the joining between the top case 101 and the bottom case 102, the positioning ribs 102p and 102q can be omitted as long as the position of the holding member 12 in the Z-axis direction is regulated adequately.

Incidentally, the case of forming the positioning ribs 102p and 102q makes the configuration complicated as described above. Therefore, as a specific example for avoiding such a complicated configuration, a positioning member having a square shape, for example, is formed on a back face of the bottom portion 12h of the holding member 12 and a positioning portion that is engageable with the positioning portion formed on the back face of the bottom portion 12h also is formed in the bottom portion 102b of the bottom case 102, which eliminate the necessity to form the positioning ribs 102p and 102q. A specific example extending this idea will be described with reference to the drawings from FIG. 8A.

FIG. 8A is a perspective view mainly showing a front side of the holding member 12. FIG. 8B is a perspective view mainly showing a back side of the holding member 12. FIG. 8C is a perspective view mainly showing a lower side of the holding member 12. The holding member 12 includes the connector placement portion 12a, the first side wall 12b, the second side wall 12c, the back wall 12d, the protrusion 12e, the hole 12f, a wall face 12g, the bottom portion 12h, a positioning member 12k and the front wall 12m. In the present invention, in the holding member 12, a side where the front wall 12m is formed with respect to the connector placement portion 12a is defined as “front”, a side where the back wall 12d is formed with respect to the connector placement portion 12a is defined as “back”, a first side wall side positioned on the left side when the back wall 12d is viewed from the front wall 12m is defined as “left”, and a second side wall side positioned on the right side when viewed from the front is defined as “right”.

The connector placement portion 12a is a space where the cable connector 11 can be placed. The first side wall 12b and the second side wall 12c are opposed to each other with the connector placement portion 12a interposed therebetween. The first side wall 12b and the second side wall 12c can regulate the position of the cable connector 11 placed in the connector placement portion 12a in the Z-axis direction. The back wall 12d is arranged behind the connector placement portion 12a, and is adjacent to the first side wall 12b and the second side wall 12c. The back wall 12d and the front wall 12m can regulate the position of the cable connector 11 placed in the connector placement portion 12a in the X-axis direction.

The protrusion 12e is a member for regulating the position of the cable connector 11 placed in the connector placement portion 12a in the X-axis direction. The protrusion 12e is formed in such a manner as to contact the second side wall 12c and the bottom portion 12h. Although the illustration is omitted, a protrusion similar to the protrusion 12e also is formed in such a manner as to contact the first side wall 12b and the bottom portion 12h. Further, although the illustration of the specific configuration is omitted, the cable connector 11 has a concave portion where the protrusion 12e can be fitted.

The hole 12f is formed for insertion of a conductive wire material (not illustrated) that is connected electrically to the cable connector 11.

The wall face 12g (see FIG. 8B) is a face on a back side of the back wall 12d. The wall face 12g is a face in the back wall 12d on a side opposite to the connector placement portion 12a. The wall face 12g has a shape and an area sufficient to close at least the opening portion 1c. In the present embodiment, the wall face 12g has an area slightly smaller than the opening area of the opening portion 1c. Note here that “a shape and an area sufficient to close the opening portion 1c” includes a shape and an area that create a slight gap between the back wall 12d and the opening portion 1c when the opening portion 1c is closed by the back wall 12d, and a shape that does not create any gap between the back wall 12d and the opening portion 1c, i.e., a shape and an area that cause the back wall 12d to be press-fitted in the opening portion 1c. The wall face 12g need not have a shape and an area sufficient to close the opening portion 1c as exemplified in the present embodiment, as long as at least the shape and the area close the opening portion 1c to the extent that a communication cable can be prevented from being attached to the cable connector 11.

The positioning member 12k (see FIG. 8C) is formed on a lower face of the bottom portion 12h. The positioning member 12k is a member for positioning the holding member 12 in a predetermined position of the first housing 1. Although the positioning member 12k is formed to have a substantially rectangular shape in a plan view, this shape merely is an example. The shape and the position of the positioning member 12k are set so as to be fitted into positioning portions 102d and 102e (described later) when the holding member 12 is placed in the first housing 1 with the front wall 12m facing the opening portion 1c side and when the holding member 12 is placed in the first housing 1 with the back wall 12d facing the opening portion 1c side.

The front wall 12m is formed at a position opposite to the back wall 12d with the connector placement portion 12a interposed therebetween. A mark or a character expressing a modular port may be put on the front wall 12m. Note here that it is not essential to provide the front wall 12m in the holding member 12.

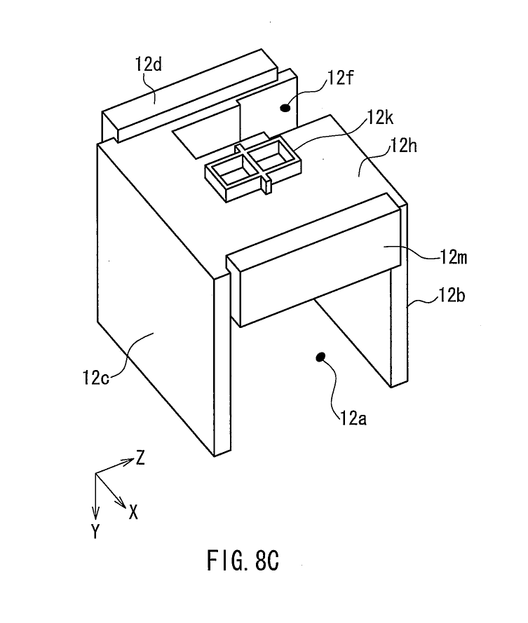

FIG. 9 is a partial perspective view of the bottom case 102 in the vicinity of the opening portion 1c of the first housing 1. As shown in FIG. 9, the bottom case 102 includes the bottom portion 102b and the side wall 102a arranged vertically on the periphery of the bottom portion 102b. The notch 102c forming the opening portion 1c is formed in the side wall 102a. The positioning portions 102d and 102e are formed integrally in the bottom portion 102b. Each of the positioning portions 102d and 102e has a substantially “square-cornered U shape” in a plan view. In a space surrounded by the positioning portions 102d and 102e, the positioning member 12k formed in the holding member 12 can be placed. Since the positioning portions 102d and 102e are formed at a position where a gap with respect to the positioning member 12k becomes minimal when the positioning member 12k is placed in the surrounded space, the position of the holding member 12 in the bottom portion 102b of the bottom case 102 can be regulated.

Hereinafter, specific configurations of the notebook computer in the case of having the modular port 10 and in the case of not having the modular port 10 will be described.

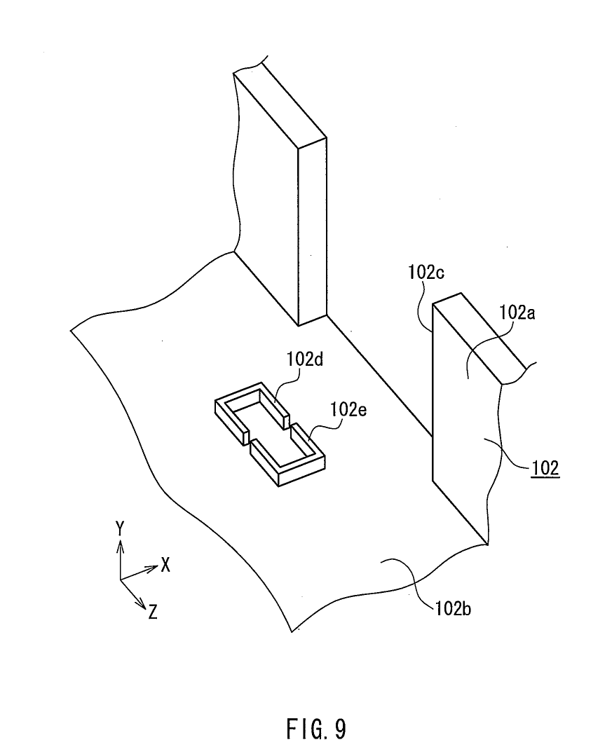

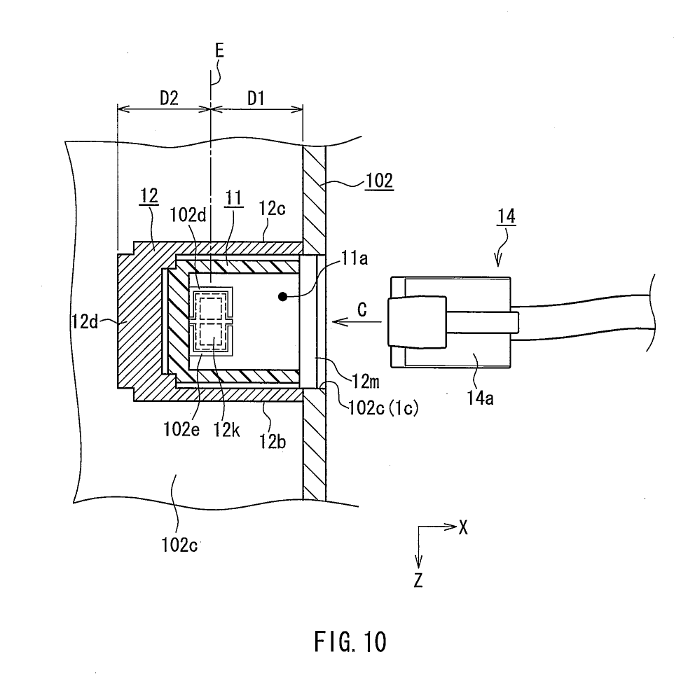

FIGS. 10 and 11 are main portion cross-sectional views of the notebook computer having the modular port 10. FIG. 10 is a cross-sectional view taken along a line W-W in FIG. 2. FIG. 11 is a cross-sectional view taken along a line V-V in FIG. 2.

As shown in FIGS. 10 and 11, when the notebook computer has the modular port 10, firstly the cable connector 11 is placed in the connector placement portion 12a of the holding member 12. At this time, the position of the cable connector 11 is regulated by the protrusion 12e (see FIG. 8A) formed in the holding member 12. Further, a conductive wire material (not illustrated) provided in the cable connector 11 is inserted in the hole 12f (see FIGS. 8A and 8B) so as to be connected electrically to an electric circuit board (not illustrated) arranged in the first housing 1.

Next, as shown in FIG. 10, the holding member 12 holding the cable connector 11 is arranged in the predetermined position of the bottom case 102, i.e., in the vicinity of the notch 102c. At this time, the holding member 12 is arranged in the predetermined position of the bottom case 102 with the front wall 12m side facing the notch 102c side. By placing the positioning member 12k shown in FIG. 8C in the space surrounded by the positioning portions 102d and 102e shown in FIG. 9, the position in a plane direction of the bottom portion 102b of the bottom case 102 is regulated.

Next, as shown in FIG. 11, the top case 101 is joined to the bottom case 102. By joining the top case 101 to the bottom case 102, a lower face 101a of the top case 101 comes into contact with or comes close to the cable connector 11 and the holding member 12. Thus, the cable connector 11 and the holding member 12 are sandwiched by the top case 101 and the bottom case 102, and hence, the position in the thickness direction (Y-axis direction) of the first housing 1 is regulated.

In this manner, the modular port 10 can be provided in the notebook computer. By this, as shown in FIG. 2, the opening portion 11a of the cable connector 11 is exposed from the first housing 1, which allows the connector 14a of the modular cable 14 to be connected to the cable connector 11 when displaced in the direction indicated by the arrow C as shown in FIG. 10.

By putting a mark or a character expressing a modular port on the front wall 12m, it is possible to notify a user that the port exposed from the opening portion 1c is a modular port.

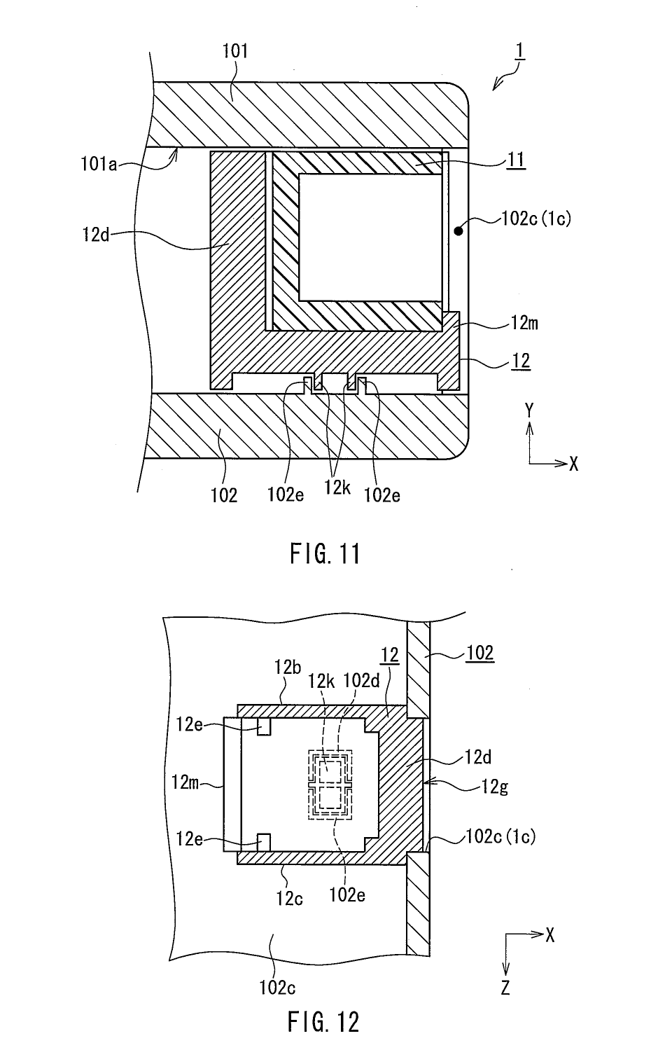

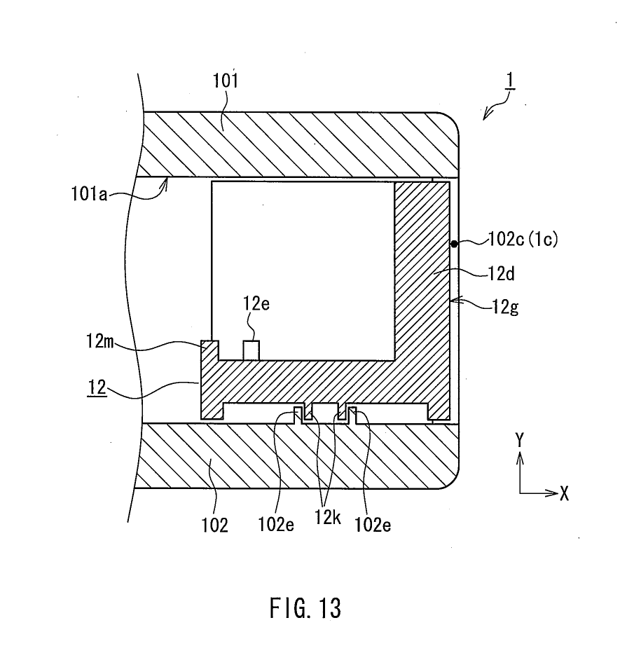

FIGS. 12 and 13 are main portion cross-sectional views of the notebook computer not having the modular port 10. FIG. 12 is a cross-sectional view taken along the line W′-W′ in FIG. 3. FIG. 13 is a cross-sectional view taken along a line V′-V′ in FIG. 3.

As shown in FIGS. 12 and 13, also in the case where the notebook computer does not have the modular port 10, the holding member 12 is arranged in the predetermined position of the bottom case 102, i.e., in the vicinity of the notch 102c. However, in this case, the holding member 12 is arranged in the predetermined position of the bottom case 102 with the back wall 12d and the wall face 12g side facing the notch 102c side. By placing the positioning member 12k of the holding member 12 in the space surrounded by the positioning portions 102d and 102e, the position in the plane direction of the bottom portion 102b of the bottom case 102 is regulated.

Next, as shown in FIG. 13, the top case 101 is joined to the bottom case 102. By joining the top case 101 to the bottom case 102, the lower face 101a of the top case 101 comes into contact with or comes close to the holding member 12. Thus, the holding member 12 is sandwiched by the top case 101 and the bottom case 102, and hence, the position in the thickness direction (Y-axis direction) of the first housing 1 is regulated.

In this manner, as shown in FIG. 3, the wall face 12g of the back wall 12d of the holding member 12 is exposed via the opening portion 1c. Further, since the wall face 12g at least has an area slightly smaller than the opening area of the opening portion 1c, a part of the back wall 12d is positioned in the opening portion 1c by placing the holding member 12 in the first housing 1 in a posture shown in FIGS. 12 and 13. Thus, the opening portion 1c can be closed by the wall face 12g.

Here, as shown in FIG. 10, the positioning member 12k is formed at a position where a distance D1, which is from a centerline E (the center of the X-axis direction) to front ends of the first side wall 12b and the second side wall 12c, and a distance D2, which is from the centerline E to the back wall 12d, become equal to each other. Further, the positioning member 12k is formed symmetrically about the centerline E. Therefore, when the holding member 12 is placed in the predetermined position of the bottom case 102 in the orientation shown in FIGS. 10 and 11, and in the orientation shown in FIGS. 12 and 13, the positioning member 12k can be arranged in the space surrounded by the positioning portions 102d and 102e. Thus, the position in the plane direction of the bottom portion 102b is regulated when the holding member 12 is placed in the predetermined position of the bottom case 102 in the orientation shown in FIGS. 10 and 11, and in the orientation shown in FIGS. 12 and 13.

[2. Effects of Embodiment, Etc.]

According to the present embodiment, by providing the back wall 12d in the holding member 12 capable of holding the cable connector 11, it is possible to close the opening portion 1c by the back wall 12d when producing the notebook computer not having the modular port 10. In other words, just changing the orientation of the holding member 12 realizes the configuration of holding the cable connector 11 in the holding member 12 and the configuration of closing the opening portion 1c by the holding member 12 selectively. Therefore, one holding member 12 can realize the notebook computer having the modular port 10 and the notebook computer not having the modular port 10. Because of this, in the case of producing the notebook computer not having the modular port 10, there is no need to prepare a lid separately, which can correspond to a plurality of specifications of communication interfaces with a reduced number of components. The reduction in the number of components reduces the cost of the notebook computer and the number of steps in assembling the notebook computer.

Further, according to the present embodiment, by forming the positioning member 12k in the holding member 12 and forming the positioning portions 102d and 102e in the bottom case 102, it is possible to place the holding member in different orientations using the positioning member 12k and the positioning portions 102d, 102e. Therefore, the configuration of positioning the holding member 12 in the bottom case 102 can be simplified, which reduces the production cost of the notebook computer.

Further, as shown in FIG. 10, since the positioning member 12k is formed symmetrically about the centerline E, the holding member 12 can be placed in the bottom case 102 in the orientation shown in FIGS. 10 and 11, or in the orientation shown in FIGS. 12 and 13. However, in the orientations other than the above, since the positioning member 12k cannot be placed in the space surrounded by the positioning portions 102d and 102e, the holding member 12 cannot be placed in the bottom case 102 in the orientations other than the orientations shown in FIGS. 10-13. Therefore, it is possible to prevent the holding member 12 from being placed in the wrong orientation in the predetermined position of the bottom case 102.

Further, according to the present embodiment, by sandwiching the holding member 12 by the top case 101 and the bottom case 102 and positioning the holding member 12 using the positioning portions 102d, 102e and the positioning member 12k, the holding member 12 can be held in the first housing 1 without using screws, etc. Therefore, the number of components can be reduced while the workability of assembling the first housing 1 can be improved. However, the configuration of positioning the holding member 12 in the upper and lower directions (Y-axis direction) is not limited to the configuration where the holding member 12 is sandwiched by the top case 101 and the bottom case 102. For example, as in the case of positioning the holding member 12 in the X-axis and the Z-axis directions, it is possible to position the holding member by forming positioning ribs, positioning members and positioning portions in the holding member, the top case 101 and/or the bottom case 102.

Further, according to the present embodiment, by putting a mark or a character expressing a modular port on the front wall 12m, it is possible to notify a user that the port exposed from the opening portion 1c is a modular port.

It is preferable that the shape and the arrangement of the back wall 12d of the holding member 12 are set such that, when the holding member 12 is attached to the first housing 1 in the orientation shown in FIGS. 12 and 13, the wall face 12g is flush with the first side face 1b of the first housing 1. Similarly, it is preferable that the shape and the arrangement of the second side wall 12c are set such that, when the holding member 12 is attached to the first housing 1 in the orientation shown in FIG. 7, the wall face 12q is flush with the first side face 1b of the first housing 1. With this configuration, in view of the appearance of the first housing 1, it is possible to make the presence of the opening portion 1c and the back wall 12d, the second side wall 12c less noticeable.

Further, it is preferable that the back wall 12d is press-fitted in the opening portion 1c when the holding member 12 is attached to the first housing 1 in the orientation shown in FIGS. 12 and 13. Similarly, it is preferable that the second side wall 12c is press-fitted in the opening portion 1c when the holding member 12 is attached to the first housing 1 in the orientation shown in FIG. 6. With this configuration, no gap is created between the holding member 12 and the opening portion 1c, thereby avoiding the intrusion of foreign matters, such as dust, into the first housing 1 via the opening portion 1c.

Further, it is preferable that at least the wall face 12g or the wall face 12q in the holding member 12 is formed of the same material as the first side face 1b of the first housing 1. Further, it is preferable that the wall face 12g or the wall face 12q has the same color as the first side face 1b of the first housing 1. With this configuration, in view of the appearance of the first housing 1, it is possible to make the presence of the opening portion 1c and the wall face 12g or the wall face 12q less noticeable.

Further, although the holding member 12 is configured to hold the cable connector 11 that is used as the modular port 10, it can be configured to hold a connector corresponding to other communication interfaces, such as a LAN port, USB port, and the like.

Further, although the positioning portions 102d and 102e are formed in the bottom case 102, they may be formed in a face in the top case 101 opposed to the bottom case 102.

The modular cable 14 in the present embodiment is an example of the communication cable. The cable connector 11 in the present embodiment is an example of the connector. The opening portion 1c in the present embodiment is an example of the opening portion. The first housing 1 in the present embodiment is an example of the housing. The holding member 12 in the present embodiment is an example of the holding member. The connector placement portion 12a in the present embodiment is an example of the notch portion. The back wall 12d in the present embodiment is an example of the wall portion. In the present embodiment, the posture of the holding member 12 in which the connector placement portion 12a faces the opening portion 1c as shown in FIGS. 10 and 11 is a first posture. In the present embodiment, the posture of the holding member 12 in which the wall face 12g faces the opening portion 1c as shown in FIGS. 12 and 13 is an example of a second posture. The positioning member 12k in the present embodiment is an example of the protrusion. The positioning portions 102d and 102e in the present embodiment are an example of the concave portion. The top case 101 and the bottom case 102 in the present embodiment are an example of a pair of the housing members.

Further, in each of the embodiments described above, the notebook computer is explained as an example of the electronic apparatus. However, the electronic apparatus is not limited to the notebook computer, and may be various types of personal computers, such as a desktop personal computer and a so-called tablet personal computer. Further, the electronic apparatus of the present embodiment is not limited to the personal computers, and may be realized as various types of electronic apparatuses having connector ports to which various types of connectors are attached, such as a personal digital assistant (PDA), a portable game machine, a portable medical equipment, a portable television, a portable Blu-ray disk, or a DVD playback equipment.

The present application is useful for the electronic apparatus having a communication interface.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An electronic apparatus that can have a connector to which a communication cable is connectable, comprising:
a housing having an opening portion to which the communication cable is insertable; and
a holding member contained in the housing and capable of holding the connector,
wherein the holding member includes a notch portion for exposing a communication cable connection portion in the connector to the outside, and a wall portion having a size sufficient to close the opening portion, and
the holding member can be placed in the housing in a first posture in which the notch portion faces the opening portion or in a second posture in which the wall portion closes the opening portion.

2. The electronic apparatus according to claim 1,
wherein the holding member has a protrusion in a face adjacent to the wall portion and a face where the notch portion is formed,
the housing has a concave portion where the protrusion can be fitted, and
the protrusion is fitted into the concave portion when the holding member is in the first posture and the second posture.

3. The electronic apparatus according to claim 2,
wherein the housing is composed of a pair of housing members, and
the holding member is sandwiched by the pair of housing members.

4. The electronic apparatus according to claim 1, wherein the wall portion has a size that can be inserted or press-fitted in the opening portion when the holding member is placed in the housing in the second posture.

5. The electronic apparatus according to claim 1, wherein a face of the wall portion exposed from the opening portion of the housing when the holding member is placed in the housing in the second posture has a shape that continues at least a surface in a vicinity of the opening portion in the housing.

6. The electronic apparatus according to claim 1, wherein a face of the wall portion exposed from the opening portion of the housing when the holding member is placed in the housing in the second posture has the same color as a surface of the housing.
